(19) United States
(12) Patent Application Publication
(10) Pub. No.: US 2005/0249023 A1
(43) Pub. Date: Nov. 10, 2005

(54) Device and method for overriding a do-not-disturb mode

(75) Inventor: Maarten Peter Bodlaender, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/526,080

(22) PCT Filed: Jul. 31, 2003
(86) PCT No.: PCT/IB03/03719

§ 371 Date: Feb. 28, 2005

(30) Foreign Application Priority Data
Sep. 2, 2002 (EP) 02078591.1

(51) Int. Cl. G11C 8/02

(52) U.S. Cl. 365/232

(57) ABSTRACT

A device for receiving messages like a combination of an alarm clock and an answering machine has a message receiving unit (11), a recording and playback unit (17), a clock (12), and controls an attention signal. The device has a do-not-disturb mode, an alarm mode, and times can be selected for the do-not-disturb mode and/or the alarm mode. In the do-not-disturb mode, messages are recorded and the attention signal is suppressed. The device has a response unit (20) for providing an override function for the remote sender for overriding a mode set by the user. Hence, the sender receives a response that the device is in the do-not-disturb mode, and has the option to generate the attention signal in spite of the do-not-disturb mode

The invention relates to a device for receiving messages, the device comprising a receiving unit for receiving a message from a remote sender, a clock for keeping time, a signal unit for controlling an attention signal, a control unit for receiving user commands and for controlling functions of the device, which functions include a do-not-disturb mode, an alarm mode and setting a selected time for the do-not-disturb mode and/or the alarm mode, a recording/playback unit for recording the message at least during the do-not-disturb mode and for reproducing a recorded message.

A device for playing recorded audio at a selected time is known from U.S. Pat. No. 5,555,536. The device comprises an alarm clock and a recorder coupled together. Recorded audio may be played at a time selected by the user. The recorder may include an answering machine for receiving messages from a telephone network. The device may be set to a do-not-disturb mode, in which mode messages are recorded on the recorder. At the time set, the messages are reproduced. A problem of the known device is that the practical operational function of the device in the do-not-disturb mode is limited.

It is therefore an object of the invention to provide a device and method for receiving messages having a more flexible operational function in the do-not-disturb mode.

The object is achieved with a device as defined in the opening paragraph, characterized in that the device comprises a response unit for providing an override function for the remote sender for overriding a mode set by the user by receiving a command from the remote sender. The override function has the effect that a selected mode, e.g. the do-not-disturb mode, is ignored. Hence, the user can be reached under the control of the sender, e.g. for a message having a high urgency in the case of an emergency.

The invention is also based on the following recognition. The known answering machine and alarm clock combinations do provide a do-not-disturb mode, in which messages are recorded automatically, and may be reproduced later, e.g. at the wake-up time. However, the inventor has seen that users may be hesitating to switch on such a do-not-disturb mode, because they cannot be reached at all during said mode. The sender will know the urgency of the message. On the other hand, the sender may be hesitant to call at a late hour with a less urgent message. The solution according to the invention is to provide the response unit that allows the sender to override the do-not-disturb mode.

In an embodiment of the device, the response unit is arranged to provide a message to the remote sender. The effect is that the sender is now aware of the options to send commands and can be instructed which commands are available. For example, in a telephone system, the response unit may provide a voice menu providing a warning that the user is asleep and a choice to either dial a one for recording a message or a two for activating the attention tone.

In a further embodiment of the device, the response unit is arranged to provide the override function by generating the attention signal immediately or at a specified time. In particular, the sender may activate the attention signal during the do-not-disturb mode. The advantage is that the remote sender has the option of controlling the time when the attention signal is generated, e.g. specifying an earlier wake-up time.

Further preferred embodiments of the device according to the invention are given in the dependent claims.

These and other aspects of the invention are apparent from and will be elucidated further with reference to the embodiments described by way of example and with reference to the accompanying drawings, in which

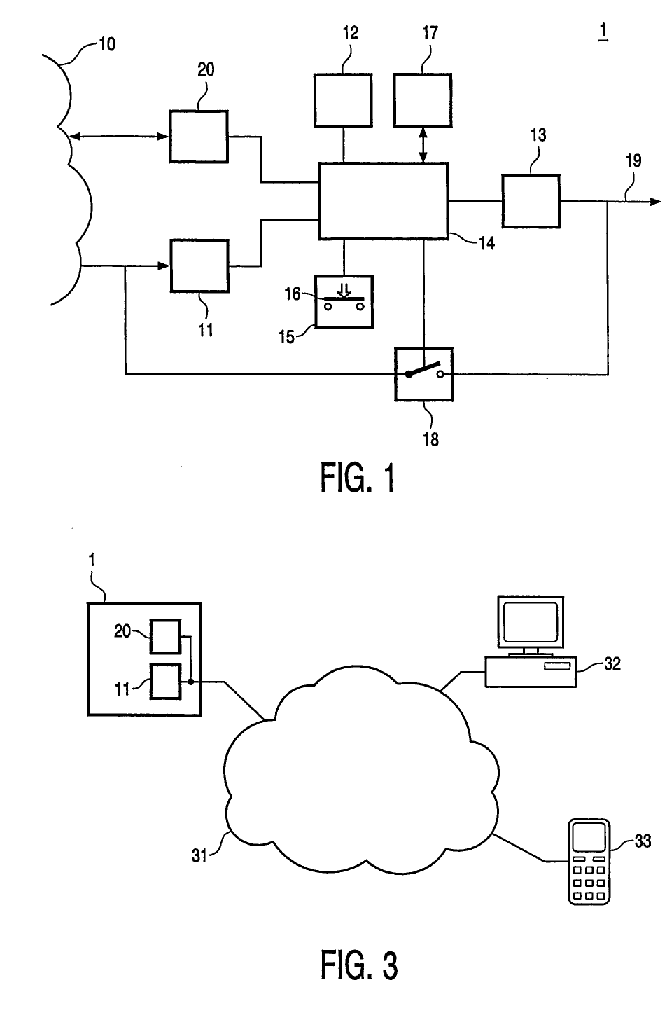

FIG. 1 shows a message receiving device,

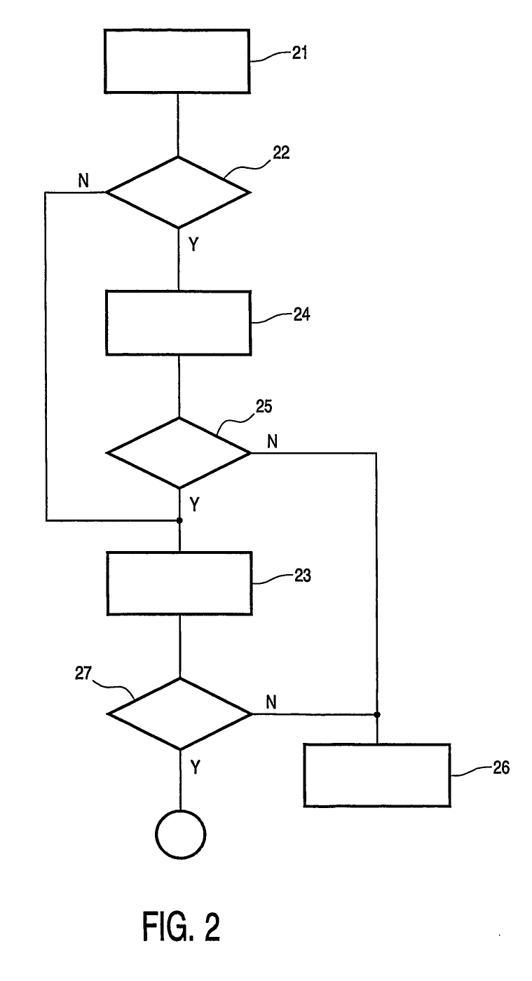

FIG. 2 shows a flow chart of response handling, and

FIG. 3 shows a data network and sending and receiving devices.

The Figures are diagrammatic and not drawn to scale. In the Figures, elements which correspond to elements already described have the same reference numerals.

FIG. 1 shows a message receiving device. The device has a receiving unit 11 for receiving a message from a remote sender via a communication network 10, a clock 12 for keeping time, a signal unit 13 for controlling an attention signal to an output 19, and a control unit 14. Further more, the device has a recording and playback unit 17 for temporarily recording messages and reproducing them at a later time. The recording function may be implemented as a tape recorder, or as a digital recording function in which audio messages are encoded according to an encoding algorithm and stored in a semiconductor memory. The control unit has an input unit 15 for receiving user commands, e.g. via user buttons 16. The control unit 14 is implemented as a processor unit having a memory and control logic. Alternatively, the control unit may be implemented as a state machine, e.g. in a dedicated IC. The control unit 14 performs basic alarm clock functions. At least one alarm time can be selected by the user for activating an alarm mode. When the clock 12 indicates the selected alarm time, the signal unit 13 is activated to generate an attention signal. The basic answering machine functions are as follows. The device is coupled to a voice network like the public telephone network. The output 19 of the device is coupled to a telephone. Alternatively, the device may comprise the necessary elements to function as a telephone, e.g. a loudspeaker for generating an audible signal and/or a handset for voice input and output. The elements above are well-known from alarm clocks, telephones and answering machines. In particular, combinations of alarm clock functions and answering machine functions are described in U.S. Pat. No. 5,555,536. The control unit 14 performs the following functions of the device.

The device has a do-not-disturb mode. The do-not-disturb mode is activated on a user command, e.g. when the user goes to sleep. Alternatively, the do-not-disturb mode may be activated on a selected time as preset by the user, e.g. at 11:00 PM every day. In an embodiment, the device is coupled to a further input device for detecting a do-not-disturb state of the user. The further input device may be a detector in a home base of a mobile phone, detecting the state that the mobile phone is positioned in a recharge/non-active mode. Alternatively, there may be a voice input device for receiving a voice command of the user and recognizing the do-not-disturb command.

In the do-not-disturb mode, the device receives incoming messages and records them. The device may include an interrupter 18 for disconnecting an external telephone during the do-not-disturb mode. Hence, the ringer signal from the public telephone network will be suppressed. The messages can be reproduced later on a user command. In an embodiment, the replay of the messages has the function of the attention signal. The user can select to reproduce the messages at a preset time, for example at the wake-up time set on the alarm clock.

The device has a response unit 20 coupled to the communication network 10 for communicating with the remote sender. The response unit generates a response message to the sender, so that the sender knows that there is an option to enter commands that will be executed in the receiving device. For example, the response message is a voice menu first stating a warning like “the user has set this machine to a do-not-disturb mode. Please press ‘one’ to record your message. If you want to wake the user: please press ‘two’ to have the phone ringing.” By receiving and executing the sender's commands, the response unit provides an override function for the remote sender for overriding a mode set by the user, for example by generating the attention signal under the control of the remote sender.

In an embodiment, the override command includes an option to set a specific time for executing the override function. A first option is to specify that a message is to be reproduced at the wake-up time set by the user. Such an option may override a selection of the user for the type of wake-up signal, e.g. a favorite radio station. A second option is to specify a specific time to produce the attention signal, e.g. at midnight or 10 minutes before the set wake-up time to allow the user to react to the message. In an embodiment, a service provider may offer the service of sending messages of a specific type to the user. For example, the user may have a contract with the service provider for a message service if a specific type of weather is expected to have an early alarm and the specific weather report.

FIG. 2 shows a flow chart of response handling. In a first step SENDER MESSAGE 21, the sender makes a connection to the receiving unit, e.g. by dialing the phone number. In a second step DO-NOT-DISTURB 22, it is determined if the user has set the device to the do-not-disturb mode. If not, the attention signal is produced in step ATTENTION 23, e.g. by transferring the ringing signal from the public telephone network to a connected telephone. If the do-not-disturb mode is set, the device will send a response message in a response step RESPONSE MENU 24. The sender may now reply by sending a remote command to override the do-not-disturb mode. If such a command is received in step RECEIVE SENDER COMMAND 25, the attention signal will be generated in step ATTENTION 23. If a command to record is received, or no command, the recording function is activated in step RECORD 26. After activating the attention signal, the device will wait for a user to respond in step USER RESPONDS 27. If the user responds, e.g. by picking up the handset, a direct communication between sender and user may follow. If not, a further response to the sender may be given and again the recording function of step RECORD 26 may be activated.

FIG. 3 shows a data network and sending and receiving devices. In an embodiment, the receiving device 1 is arranged as a universal inbox to be coupled to a data network, e.g. the Internet 31. The universal inbox device 1 may be implemented as a stand-alone device directly coupled to the data network, or as a function in a computer, e.g. a PC, a server or home management system. The functions of the device are then implemented by suitable software in combination with the available hardware in the computer. The receiving unit 11 and the response unit 20 are arranged to receive and transmit data messages via the data network. Several types of devices, such as a computer 32 or a mobile phone 33, may be coupled to the data network. Such devices allow a sender to send messages to the device 1, e.g. e-mail messages or SMS messages. The universal inbox receives different types of messages. The response function is realized by automatically generating a response message if the user has set a do-not-disturb mode. In general, a do-not-disturb mode is a mode in which no attention signal is generated when the message is received. The do-not-disturb mode for a universal inbox type embodiment may include a working mode wherein the user has the device switched on, but is involved in other activities. The remote sender may then draw the user's attention by issuing a remote command to produce the attention signal. In an embodiment, commands of the sender may be transferred in a separate predefined type of data messages, e.g. using a code given to the sender in the automatically generated response message.

In an embodiment, the device is arranged to reproduce messages after processing. In a first embodiment, the messages are summarized, e.g. by only reproducing the first 15 seconds of each message. Data messages may be summarized by just mentioning the sender, size and time of arrival, or by just mentioning the number received. In a second embodiment, the messages originally sent and recorded as data messages are vocalized, e.g. by translating text messages into voice messages.

In an embodiment, the device is arranged to generate an attention signal depending on the messages received. For example, the attention signal may indicate the number of messages received, or the loudness or sound pattern may depend on the number of messages. The content of the message as indicated by the sender may be used to determine the attention signal, e.g. a specific tune may indicate an urgency level indicated by the sender.

In an embodiment, the receiving device is arranged to recognize the sender, e.g. by comparing a user ID received via a data network or the sender's telephone number received via the public telephone network to a known list of senders. The device may provide the list of senders to be entered by the user. The response may be different for specific senders. In addition, specific senders may have more commands available than others.

Although the invention has been mainly explained by way of embodiments using the public telephone network, it is also suitable for other any communication networks such as a home network. It is noted that in this document the use of the verb ‘comprise’ and its conjugations does not exclude the presence of elements or steps other than those stated in the claims and the article ‘a’ or ‘an’ preceding an element does not exclude the presence of a plurality of such elements. Any reference signs do not limit the scope of the claims, while the invention and every unit or means mentioned may be implemented by suitable hardware and/or software and several ‘means’ or ‘units’ may be represented by the same item. Furthermore, the scope of the invention is not limited to the embodiments, and the invention resides in each and every novel feature or combination of features described above.

1. A device for receiving messages, the device comprising
a receiving unit (11) for receiving a message from a remote sender,
a clock (12) for keeping time,
a signal unit (13) for controlling an attention signal,
a control unit (14) for receiving user commands and for controlling functions of the device, which functions include a do-not-disturb mode, an alarm mode and setting a selected time for the do-not-disturb mode and/or the alarm mode,
a recording/playback unit (17) for recording the message at least during the do-not-disturb mode and for reproducing a recorded message,
characterized in that the device comprises
a response unit (20) for providing an override function for the remote sender for overriding a mode set by the user by receiving a command from the remote sender.

2. A device as claimed in claim 1, wherein the response unit (20) is arranged to provide a message to the remote sender, and/or to provide the override function by generating the attention signal immediately or at a specified time.

3. A device as claimed in claim 1, wherein the receiving unit (11) is arranged to communicate with a voice network, in particular the telephone network, and wherein the signal unit (13) is used for controlling a ringer signal from the voice network, in particular suppressing the ringer signal during the do-not-disturb mode.

4. A device as claimed in claim 1, wherein the receiving unit (11) is arranged to communicate with a data network, in particular the Internet.

5. A device as claimed in claim 4, wherein the signal unit (13) is used for generating the attention signal based on the content or number of messages received via the data network.

6. A device as claimed in claim 1, wherein the recording/playback unit (17) is arranged to reproduce the recorded message as the attention signal and/or to reproduce a summary of the recorded message.

7. A device as claimed in claim 4, wherein the recording/playback unit (17) is arranged to reproduce a vocalized version of the recorded message.

8. A method of receiving messages, the method comprising the steps of
receiving a message from a remote sender,
keeping time,
controlling an attention signal,
receiving user commands,
controlling functions of the device, which functions include a do-not-disturb mode, an alarm mode and setting a selected time for the do-not-disturb mode and/or the alarm mode,
recording the messages at least during the do-not-disturb mode, and
reproducing a recorded message,
characterized in that the method also comprises the step of
providing an override function for the remote sender for overriding a mode set by the user by receiving a command from the remote sender.

9. A computer program product for receiving messages, which program is operative to cause a processor to perform the method as claimed in claim 8.

10. A method of sending a message to a user, the method comprising the steps of
making a connection to a user system for receiving messages as claimed in claim 1,
sending commands to the user system for overriding a mode set by the user for immediately reproducing the message or for recording the message and reproducing the message at a specified time, and
sending the message contents.
